(19) United States
(12) Patent Application Publication
(10) Pub. No.: US 2016/0120051 A1
(43) Pub. Date: Apr. 28, 2016

(54) PACKAGE, MANUFACTURING METHOD OF PACKAGE, ELECTRONIC DEVICE, ELECTRONIC APPARATUS, AND MOVING OBJECT

(71) Applicant: Seiko Epson Corporation, Tokyo (JP)

(72) Inventors: Tomoyuki KAMAKURA, Matsumoto (JP); Motoko KONDO, Asahi (JP)

(21) Appl. No.: 14/886,400

(22) Filed: Oct. 19, 2015

(30) Foreign Application Priority Data
Oct. 24, 2014 (JP) 2014-217044

(51) Int. Cl. H05K 5/02; H03B 5/32; H01B 3/08; H05K 5/06; H01B 3/00

(52) U.S. Cl. CPC H05K 5/0239; H05K 5/066; H01B 3/004; H01B 3/08; H03B 5/32

(57) ABSTRACT

A package includes a package base, a lid that is disposed to overlap the package base in a plan view when viewed in a thickness direction of the package base and has light permeability, and low melting point glass that is disposed between the package base and the lid, and bonds the package base and the lid, in which the low melting point glass has a region of which a width in a cross section along the thickness direction is widened toward a bonding surface of the lid.

### CROSS REFERENCE

This application claim benefit of Japanese Application No. 2014-217044, filed on Oct. 24, 2014. The disclosure of the prior application is hereby incorporated by reference herein in its entirety.

### BACKGROUND

1. Technical Field

The present invention relates to a package, a manufacturing method of the package, an electronic device including the package, and an electronic apparatus and a moving object which include the electronic device.

2. Related Art

In the related art, as an electronic device where a quartz crystal piece as an electronic component is enclosed in a set of container members as a package, a surface-mounting quartz crystal oscillator (hereinafter, referred to as a quartz crystal oscillator) having a configuration, in which a circulating concave groove is provided in an outer periphery of one surface facing the set of container members, low melting point glass is applied to the outer periphery of the surface including the concave groove, and an outer surface periphery of the other surface facing the container members is bonded by firing of the low melting point glass, has been known (for example, see JP-A-2012-4696).

Since the quartz crystal oscillator has the concave groove on one side of the container member, an arcuate radius of curvature of a top portion becomes large due to surface tension of the low melting point glass, the top portion maintains an obtuse angle, and then the top portion is close to flat shape compared to a case where there is no concave groove.

Thus, in the quartz crystal oscillator, since a contact area between the low melting point glass and the other side of the container member becomes large, it is possible to increase bonding strength of one side and the other side of the container member compared to a case where there is no concave groove.

However, in the quartz crystal oscillator described above, the bonding strength between one side of the container member having the concave groove and the low melting point glass is improved compared to the case where there is no concave groove, but improvement of the bonding strength between the other side of the container member having no concave groove and the low melting point glass is insufficient and there is room for improvement.

### SUMMARY

An advantage of some aspects of the invention is to solve at least a part of the problems described above, and the invention can be implemented as the following forms or application examples.

### Application Example 1

A package according to this application example includes a base substrate; a lid body that is disposed to overlap the base substrate in a plan view when viewed in a thickness direction of the base substrate and has light permeability; and low melting point glass that is disposed between the base substrate and the lid body, and bonds the base substrate and the lid body. The low melting point glass has a region of which a width in a cross section along the thickness direction is widened toward a bonding surface of the lid body.

According to this configuration, the package has the region of the low melting point glass, which is disposed between the base substrate (corresponding to one of the container members) and the lid (corresponding to the other of the container members) and bonds the base substrate and the lid body, and of which the width in the cross section along the thickness direction is widened toward the bonding surface of the lid body.

Thus, in the package, the width in the cross section of a bonding area (contact area) between the low melting point glass and the lid body is increased more than another case (for example, a case where the width is widened from the bonding surface of the lid body to the bonding surface of the base substrate, or a case where the width is constant from the bonding surface of the base substrate to the bonding surface of the lid body). Thus, it is possible to improve bonding strength between the low melting point glass and the lid body.

As a result, in the package, it is possible to improve the bonding strength between the base substrate and the lid body.

### Application Example 2

In the package according to the application example, it is preferable that the lid body is glass.

With this configuration, since the lid body is glass, compatibility (affinity) of the package with the low melting point glass is good due to physical properties thereof and it is possible to reliably bond the lid body to the base substrate through the low melting point glass.

### Application Example 3

In the package according to the application example, it is preferable that a thickness of the low melting point glass is in a range of 10 μm or more and 100 μm or less.

With this configuration, in the package, since the thickness of the low melting point glass is in the range of 10 μm or more and 100 μm or less, the cross section shape described above is formed and it is possible to ensure sufficient bonding strength.

Moreover, if the thickness of the low melting point glass is less than 10 μm, it is not possible to ensure sufficient bonding strength due to lack of a glass component. If the thickness of the low melting point glass exceeds 100 μm, it is not possible to ensure sufficient bonding strength due to a decrease in allowable shear stress of the low melting point glass.

### Application Example 4

In the package according to the application example, it is preferable that the low melting point glass contains metal.

With this configuration, since the low melting point glass contains metal, for example, the package is likely to absorb energy by application of the energy beam such as a laser beam.

As a result, in the package, it is possible to bond the base substrate and the lid body by melting of the low melting point glass due to application of the energy beam.

### Application Example 5

In the package according to the application example, it is preferable that the low melting point glass is housed on the inside of the lid body in a plan view when viewed in the thickness direction.

With this configuration, in the package, since the low melting point glass is housed on the inside of the lid body in the plan view when viewed in the thickness direction, for example, when the energy beam such as the laser beam is transmitted through the lid body and is applied to the low melting point glass, and the base substrate and the lid body are bonded by melting of the low melting point glass, it is possible to reduce scattering of the melted low melting point glass to a periphery.

### Application Example 6

A manufacturing method of a package according to this application example includes preparing a base substrate on which low melting point glass is disposed and a lid body having light permeability; and bonding the base substrate and the lid body by applying an energy beam from the lid body side to the low melting point glass in a state where the base substrate and the lid body are overlapped through the low melting point glass.

With this configuration, in the manufacturing method of the package, bonding the base substrate and the lid body is performed by applying the energy beam from the lid body side to the low melting point glass in a state where the base substrate and the lid body are overlapped through the low melting point glass.

Thus, in the manufacturing method of the package, wettability of the bonding surface of the lid body is improved (bonding surface is activated) due to application of the energy beam and it is possible to improve bonding strength between the lid body and the low melting point glass.

### Application Example 7

In the manufacturing method of a package according to the application example, it is preferable that the bonding includes controlling a distance between the base substrate and the lid body.

With this configuration, since the manufacturing method of the package includes controlling the distance between the base substrate and the lid body in the bonding, it is possible to control the thickness of the low melting point glass and sufficiently ensure the bonding strength between the base substrate and the lid body.

### Application Example 8

In the manufacturing method of a package according to the application example, it is preferable that in the bonding, intensity distribution of the energy beam is flattened in a center portion of the energy beam.

With this configuration, in the manufacturing method of the package, since in the bonding, the intensity distribution of the energy beam is flattened in the center portion of the energy beam, melting of the low melting point glass is substantially uniformly performed.

As a result, in the manufacturing method of the package, it is possible to reliably perform bonding between the base substrate and the lid body through the low melting point glass.

### Application Example 9

In the manufacturing method of a package according to the application example, it is preferable that in the bonding, an irradiation area of the energy beam is greater than a plane area of the low melting point glass.

With this configuration, in the manufacturing method of the package, since in the bonding, the irradiation area of the energy beam is greater than the plane area of the low melting point glass, it is possible to activate the bonding surface of the lid body in a range wider than the low melting point glass (wettability is improved).

As a result, in the manufacturing method of the package, since the low melting point glass is wetted and widened on the bonding surface of the lid body, it is possible to improve bonding strength between the lid body and the low melting point glass.

### Application Example 10

An electronic device according to this application example includes the package according to any one of the application examples described above; and an electronic component that is housed in the package.

With this configuration, since the electronic device of this configuration includes the package according to any one of the application examples described above and the electronic component that is housed in the package, it is possible to achieve the effects described in any one of the application examples described above, to improve reliability, and to exert excellent performance.

### Application Example 11

An electronic apparatus according to this application example includes the electronic device according to the application example described above.

With this configuration, since the electronic apparatus of the configuration includes the electronic device according to the application example described above, it is possible to achieve the effects described in the application example described above, to improve reliability, and to exert excellent performance.

### Application Example 12

A moving object according to this application example includes the electronic device according to the application example described above.

With this configuration, since the moving object of the configuration includes the electronic device according to the application example described above, it is possible to achieve the effects described in the application example described above, to improve reliability, and to exert excellent performance.

### BRIEF DESCRIPTION OF THE DRAWINGS

The invention will be described with reference to the accompanying drawings, wherein like numbers reference like elements.

FIGS. 1A to 1C are schematic views illustrating a schematic configuration of a quartz crystal oscillator, FIG. 1A is a schematic plan view, FIG. 1B is a schematic sectional view that is taken along line A-A of FIG. 1A, and FIG. 1C is an enlarged view of B portion of FIG. 1B.

FIG. 2 is a schematic sectional view of main portions.

FIG. 3 is a flowchart illustrating main manufacturing steps of a manufacturing method of the quartz crystal oscillator.

FIGS. 4A to 4D are schematic sectional views illustrating the main manufacturing steps in order.

FIG. 5 is a schematic perspective view illustrating a cellular phone as an electronic apparatus.

FIG. 6 is a schematic perspective view illustrating a vehicle as a moving object.

### DESCRIPTION OF EXEMPLARY EMBODIMENTS

Hereinafter, an embodiment embodying the invention will be described with reference to the drawings.

### EMBODIMENT

Initially, a configuration of a quartz crystal oscillator as an example of an electronic device is described.

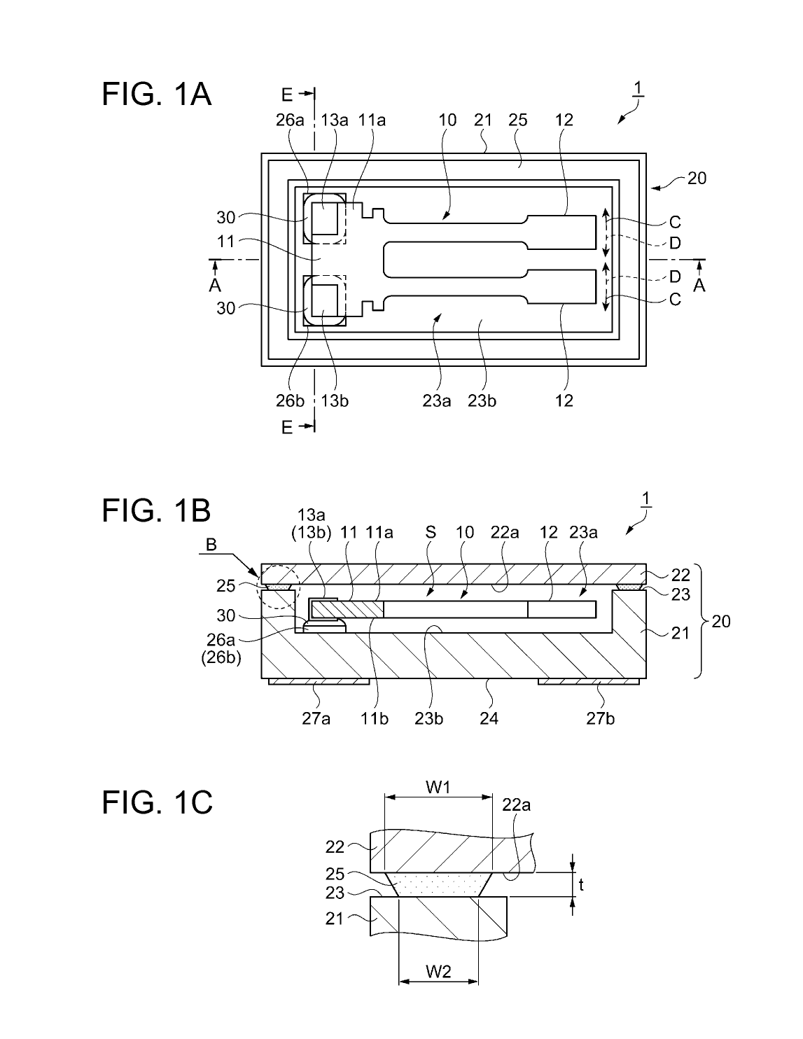

FIGS. 1A to 1C are schematic views illustrating a schematic configuration of the quartz crystal oscillator, FIG. 1A is a schematic plan view, FIG. 1B is a schematic sectional view that is taken along line A-A of FIG. 1A, and FIG. 1C is an enlarged view of B portion of FIG. 1B. In addition, in FIG. 1A, for the sake of convenience, a lid body is omitted. Furthermore, for the sake of clarity, dimensional ratios of respective components are different from actual values.

As illustrated in FIGS. 1A to 1C, a quartz crystal oscillator 1 includes a package 20 and a quartz crystal vibration piece 10 as an electronic component accommodated in the package 20.

The quartz crystal vibration piece 10 is a plate-like quartz crystal substrate which is obtained by cutting out at a predetermined angle from a gemstone of the quartz crystal and the like, and includes a substantially rectangular base section 11 and a pair of vibration arms 12 extending from one end of the base section 11 side by side.

Since the quartz crystal vibration piece 10 configures a tuning fork with the base section 11 and the pair of vibration arms 12, the quartz crystal vibration piece 10 is referred to as a tuning-fork vibration piece.

The base section 11 of the quartz crystal vibration piece 10 is provided with lead electrodes 13a and 13b drawn from excitation electrodes (not illustrated) provided in the pair of vibration arms 12.

The lead electrodes 13a and 13b wrap around from one main surface 11a of the base section 11 to the other main surface 11b via a side surface, and are provided in both main surfaces 11a and 11b of the base section 11.

The excitation electrodes and the lead electrodes 13a and 13b are, for example, formed of metal coating of a configuration in which gold (Au) or metal mainly composed of Au is laminated on chromium (Cr) as a base layer.

The package 20 has a package base 21 as a base substrate, a lid 22 as a lid body having light transmissibility that is disposed to overlap the package base 21 in a plan view when viewed in a thickness direction of the package base 21, and low melting point glass 25 that is disposed between the package base 21 and the lid body 22 and bonds the package base 21 and the lid body 22. The package 20 is configured in a substantially rectangular shape.

The package base 21 is substantially plate shaped which is substantially rectangular and has a first main surface 23 and a second main surface 24 which are in a front-and-rear relationship with each other, and includes a concave section 23a accommodating the quartz crystal vibration piece 10 in the first main surface 23.

The lid 22 has a plate shape having substantially the same plane size as that of the package base 21, is disposed on the first main surface 23 side of the package base 21, and covers the concave section 23a of the package base 21.

The low melting point glass 25 is disposed in a frame shape along an outer periphery portion of the first main surface 23 of the package base 21 and bonds the package base 21 and the lid 22.

Here, the low melting point glass 25 has a region (region of W1>W2) of a width in a cross section (when described in detail, a cross section that is taken along a thickness direction of the package base 21 and is taken along a plane orthogonal to an extending direction of the low melting point glass 25 (here, cross sections of FIGS. 1B and 1C)) along the thickness direction of the package base 21 is widened toward a bonding surface 22a of the lid 22.

Furthermore, it is preferable that a thickness t of the low melting point glass 25 is in a range of 10 μm or more and 100 μm or less. Moreover, adjustment of the thickness t can be performed by using a granular gap material.

Furthermore, it is preferable that the low melting point glass 25 is accommodated on the inside of the lid 22 in a plan view when viewed from the thickness direction of the package base 21.

For the package base 21, a ceramic-based insulating material such as an aluminum oxide sintered body, a mullite sintered body, an aluminum nitride sintered body, a silicon carbide sintered body, and a glass ceramic sintered body in which a ceramic green sheet is molded, laminated, and fired, or quartz crystal, glass, silicon (high-resistance silicon), and the like are used.

For the lid 22, for example, glass of which light transmittance is 90% or more such as borosilicate glass having light transmitting properties, quartz crystal, and the like are used.

Moreover, for the lid 22, a material of which thermal expansion coefficient is approximate or substantially equal to that of the package base 21 is preferable from the viewpoint of reduction of thermal stress.

For the low melting point glass 25, for example, low melting point glass containing metal such as vanadium (V) is used. Moreover, the low melting point glass is glass of which a glass transition temperature is 600° C. or less.

A bottom surface 23b of the concave section 23a of the package base 21 is provided with internal terminals 26a and 26b in positions facing extraction electrodes 13a and 13b of the quartz crystal vibration piece 10.

The quartz crystal vibration piece 10 is configured such that the extraction electrodes 13a and 13b are bonded to the internal terminals 26a and 26b through epoxy-based, silicone-based, or polyimide-based conductive adhesive 30 in which a conductive material such as metal filler is mixed.

The quartz crystal oscillator 1 is configured such that in a state where the quartz crystal vibration piece 10 is bonded to the internal terminals 26a and 26b of the package base 21, the concave section 23a of the package base 21 is covered by the lid 22, the package base 21 and the lid 22 are bonded through the low melting point glass 25, and thereby an internal space S configured to include the concave section 23a of the package base 21 and the lid 22 is hermetically sealed.

An inside of the internal space S of the package 20 that is hermetically sealed is in a depressurized vacuum state (high vacuum state) or in a state where an inert gas such as nitrogen, helium, and argon is filled.

Both end portions of the second main surface 24 of the package base 21 in a longitudinal direction (right and left direction on a paper surface) are provided with the external electrodes 27a and 27b having a substantially rectangular planar shape.

The external electrode 27a is connected to the internal terminal 26a led to the extraction electrode 13a of the quartz crystal vibration piece 10 by internal wiring (not illustrated) and the external electrode 27b is connected to the internal terminal 26b led to the extraction electrode 13b of the quartz crystal vibration piece 10 by internal wiring.

Moreover, for example, the internal terminals 26a and 26b, and the external electrodes 27a and 27b are made of metal coating by laminating each coating of nickel (Ni), gold (Au), and the like on a metallization layer of tungsten (W), molybdenum (Mo), and the like by plating.

For example, the pair of vibration arms 12 of the quartz crystal vibration piece 10 resonate (oscillate) alternately in arrow directions C and D at a predetermined frequency by exciting bending vibration by a driving signal applied from an oscillator circuit integrated within an IC chip of an electronic apparatus via the external electrodes 27a and 27b, and the quartz crystal oscillator 1 outputs a resonance signal (oscillation signal) from the external electrodes 27a and 27b.

As described above, the quartz crystal oscillator 1 achieves the following effects for each category.

The package 20 has the region of the low melting point glass 25, which is disposed between the package base 21 and the lid 22, and bonds the package base 21 and the lid 22, and of which the width in the cross section (cross sections of FIGS. 1B and 1C) along the thickness direction of the package base 21 is widened toward the bonding surface 22a of the lid 22 (W1>W2).

Thus, in the package 20, the width in the cross section shape of a bonding area (contact area) between the low melting point glass 25 and the lid 22 is increased more than another case (for example, a case where the width is widened from the bonding surface 22a of the lid 22 to the bonding surface (first main surface 23) of the package base 21, or a case where the width is constant from the bonding surface (first main surface 23) of the package base 21 to the bonding surface 22a of the lid 22). Thus, it is possible to improve bonding strength between the low melting point glass 25 and the lid 22.

As a result, in the package 20, it is possible to improve the bonding strength between the package base 21 and the lid 22.

Furthermore, if the lid 22 is glass (particularly, borosilicate glass), compatibility (affinity) of the package 20 with the low melting point glass 25 is good and it is possible to reliably bond the lid 22 to the package base 21 through the low melting point glass 25.

Furthermore, in the package 20, since the thickness t of the low melting point glass 25 is in the range of 10 μm or more and 100 μm or less, the cross section (cross section of FIGS. 1B and 1C) of the low melting point glass 25 described above is formed and it is possible to ensure sufficient bonding strength.

Moreover, if the thickness t of the low melting point glass 25 is less than 10 μm, it is not possible to ensure sufficient bonding strength due to lack of a glass component. If the thickness t of the low melting point glass 25 exceeds 100 μm, it is not possible to ensure sufficient bonding strength due to a decrease in allowable shear stress of the low melting point glass 25.

Furthermore, since the low melting point glass 25 contains metal (here, vanadium (V)), for example, the package 20 is likely to absorb energy (optical energy) by application of an energy beam such as a laser beam.

As a result, in the package 20, the low melting point glass 25 is melted by absorption of the optical energy due to application of the energy beam and generation of thermal energy therewith and it is possible to bond the package base 21 and the lid 22.

Furthermore, in the package 20, if the low melting point glass 25 is housed on the inside of the lid 22 in the plan view when viewed in the thickness direction, for example, when the energy beam such as the laser beam is transmitted through the lid 22 and is applied to the low melting point glass 25, and the package base 21 and the lid 22 are bonded by melting of the low melting point glass 25, it is possible to reduce scattering of the melted low melting point glass 25 to a periphery.

Since the quartz crystal oscillator 1 includes the package 20 and the quartz crystal vibration piece 10 accommodated in the package 20, the effects described above are achieved, reliability is improved, and it is possible to exert excellent performance.

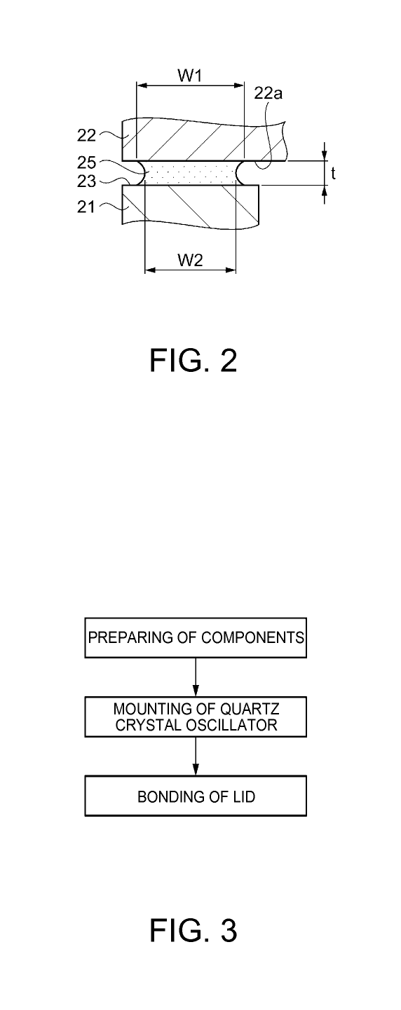

Moreover, as illustrated in a schematic sectional view of the main portions of FIG. 2, even if the cross section (cross sections of FIGS. 1B and 1C) of the low melting point glass 25 along the thickness direction of the package base 21 has a shape in which a center portion in the thickness direction is curved in a width direction, the package 20 has the region (region of W1>W2) of which the width in the cross section is widened toward a bonding surface 22a of the lid 22.

Next, an example of a manufacturing method of the quartz crystal oscillator 1 will be described as a manufacturing method of the package 20.

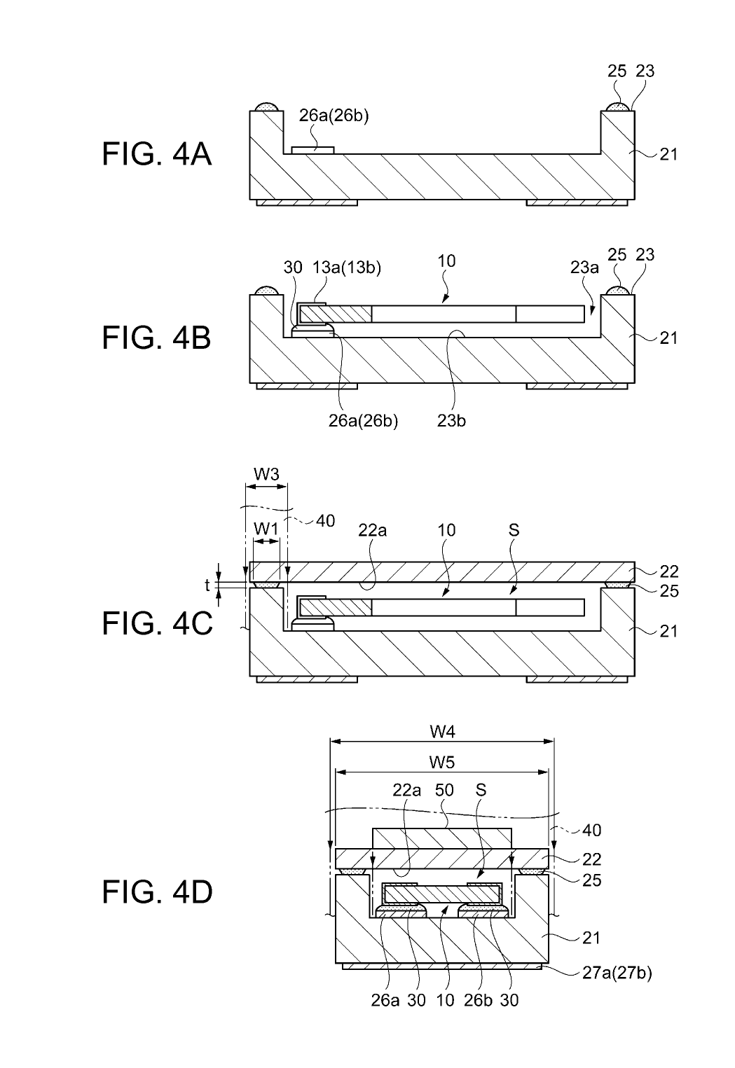

FIG. 3 is a flowchart illustrating main manufacturing steps of the manufacturing method of the quartz crystal oscillator. FIGS. 4A to 4D are schematic sectional views illustrating the main manufacturing steps in order. Moreover, cross sectional positions of each view are the same as those of FIG. 1B except FIG. 4D.

As illustrated in FIG. 3, the manufacturing method of the quartz crystal oscillator 1 includes a preparing step of components, a mounting step of the quartz crystal vibration piece, and a bonding step of the lid as a bonding step.

### Preparing Step of Components

First as illustrated in FIG. 4A, the low melting point glass 25 is disposed on the outer periphery portion of the first main surface 23 in the frame shape and the package base 21 that is temporarily fired, the lid 22, and the quartz crystal vibration piece 10 accommodated in the package 20 are prepared. Moreover, for the sake of convenience, only the package base 21 is illustrated in FIG. 4A.

### Mounting Step of Quartz Crystal Vibration Piece

Then, as illustrated in FIG. 4B, conductive adhesive 30 is applied on the internal terminals 26a and 26b provided in the bottom surface 23b of the concave section 23a of the package base 21 using a coating device such as a dispenser.

Then the quartz crystal vibration piece 10 is disposed such that the extraction electrodes 13a and 13b face the internal terminals 26a and 26b, and is mounted (attached) on the package base 21 by heating and curing the conductive adhesive 30.

### Bonding Step of Lid

Then as illustrated in FIG. 4C, in a state where the package base 21 and the lid 22 are overlapped through the low melting point glass 25, the laser beam 40 as the energy beam is applied from the lid 22 side to the low melting point glass 25, and the package base 21 and the lid 22 are bonded.

In this case, it is preferable that a laser beam 40 is applied using a fiber laser or a YAG laser of which a wavelength is 808 nm, 980 nm, 1080 nm, and the like, and on conditions that an output is 5 W to 30 W, and a scanning speed is approximately 0.5 mm/sec to 50 mm/sec.

Here, the laser beam 40 is applied as a single stroke along an extending direction of the low melting point glass 25, melts the low melting point glass 25, and bonds the package base 21 and the lid 22. Moreover, since the low melting point glass 25 contains metal such as vanadium (V), thermal energy is generated by absorbing energy (optical energy) of the laser beam 40 and for example, the low melting point glass 25 is melted at approximately 300° C.

Furthermore, it is preferable that intensity distribution of the energy of the laser beam 40 is flattened at a center portion (here, a portion corresponding to a most region of the width W1 of the low melting point glass 25) of the laser beam 40 (curve indicating a change in the intensity becomes a gentle mountain shape).

Furthermore, as illustrated in FIG. 4C, it is preferable that an application area (for the sake of convenience, here, an application width W3 of the laser beam 40) of the laser beam 40 is greater than a plane area (for the sake of convenience, here, the width W1 of the low melting point glass 25) of the low melting point glass 25. Moreover, here, for the sake of convenience, the laser beam 40 is indicated as parallel light.

Furthermore, in this case, it is preferable that a step for controlling a distance between the package base 21 and the lid 22 is provided.

Specifically, for example, a method is included in which a granular (spherical) gap material (for example, silica and the like) having a predetermined diameter is mixed to the low melting point glass 25, and the laser beam 40 is applied while pressing the lid 22, and thereby the thickness t (in other words, the distance between the package base 21 and the lid 22) of the low melting point glass 25 is adjusted so as to be within the range of 10 μm or more and 100 μm or less.

In addition, a method is included in which the distance between the package base 21 and the lid 22 is controlled by vertical movement (movement in the thickness direction of the lid 22) of a device (for example, a vacuum chuck) holding the lid 22.

Moreover, when applying the laser beam 40, in order to reduce variation of a position of the lid 22 in a plane direction, it is preferable to temporarily fix the lid 22 at a plurality of places in advance by locally applying the laser beam 40.

Furthermore, when the internal space S is made to be a vacuum state, the package base 21 and the lid 22 are bonded by applying the laser beam 40 in vacuum such as an inside of a vacuum chamber.

Moreover, as illustrated in FIG. 4D, application of the laser beam 40 is performed such that a mask 50 absorbing the laser beam 40 is mounted on the lid 22, covers the quartz crystal vibration piece 10, the conductive adhesive 30, and the like, and then an application width W4 of the laser beam 40 may be greater than a width W5 of the lid 22. Moreover, FIG. 4D is a sectional view that is taken along line E-E of FIG. 1A.

Thus, the application of the laser beam 40 is completed only by scanning from one end portion to the other end portion of the lid 22 in the longitudinal direction, an application time of the laser beam 40 can be shortened, and productivity is improved compared to the application method of the single stroke described above.

Moreover, in this case, the application width of the laser beam 40 is greater than the width of the lid 22 in the longitudinal direction and scanning of the laser beam 40 may be performed from one end to the other end of the lid 22 in a direction orthogonal to the longitudinal direction. Thus, it is possible to further shorten the application time of the laser beam 40 and to further improve the productivity.

The quartz crystal oscillator 1 as illustrated in FIGS. 1A to 1C is obtained by going through the steps described above and the like.

As described above, in the manufacturing method of the quartz crystal oscillator 1 as the manufacturing method of the package 20, the package base 21 and the lid 22 are bonded by applying the laser beam 40 from the lid 22 side to the low melting point glass 25 in a state where the package base 21 and the lid 22 are overlapped through the low melting point glass 25.

Thus, in the manufacturing method of the quartz crystal oscillator 1, wettability of the bonding surface 22a is improved (bonding surface 22a is activated) by removing foreign matter such as hydroxyl and the like attached to the bonding surface 22a of the lid 22 and the low melting point glass 25 is wetted and widened in the bonding surface 22a by application of the laser beam 40.

Thus, in the manufacturing method of the quartz crystal oscillator 1, since a contact area (bonding area) between the lid 22 and the low melting point glass 25 is increased, it is possible to improve the bonding strength between the lid 22 and the low melting point glass 25.

As a result, in the manufacturing method of the quartz crystal oscillator 1, it is possible to improve the bonding strength between the package base 21 and the lid 22.

Furthermore, in the manufacturing method of the quartz crystal oscillator 1, since the step for controlling the distance between the package base 21 and the lid 22 is included in the bonding step of the lid, it is possible to control the thickness t of the low melting point glass 25 and to sufficiently ensure the bonding strength between the package base 21 and the lid 22.

Furthermore, in the manufacturing method of the quartz crystal oscillator 1, since the intensity distribution of the laser beam 40 in the bonding step of the lid is flattened in the center portion of the laser beam 40, melting of the low melting point glass 25 is substantially uniformly performed.

As a result, in the manufacturing method of the quartz crystal oscillator 1, it is possible to reliably perform the bonding between the package base 21 and the lid 22 through the low melting point glass 25.

Furthermore, in the manufacturing method of the quartz crystal oscillator 1, since the application area of the laser beam 40 is greater than the plane area of the low melting point glass 25 in the bonding step of the lid, it is possible to activate (improve wettability) the bonding surface 22a of the lid 22 in a range wider than the low melting point glass 25.

As a result, in the manufacturing method of the quartz crystal oscillator 1, since the low melting point glass 25 is wetted and widened in the bonding surface 22a of the lid 22, the contact area between the low melting point glass 25 and the lid 22 is increased and it is possible to improve the bonding strength between the low melting point glass 25 and the lid 22.

Moreover, here, the method of separately manufacturing the quartz crystal oscillator 1 is described, but a method may be employed in which at least one of the package base 21 and the lid 22 is formed in a multi-pattern wafer shape, the plurality are collectively manufactured, and then the plurality are divided individually by using a dicing machine and the like.

Moreover, the low melting point glass 25 is not disposed in the package base 21 but may be disposed in the bonding surface 22a of the lid 22.

### Electronic Apparatus

Next, as an electronic apparatus including the electronic device described above, a cellular phone is described as an example.

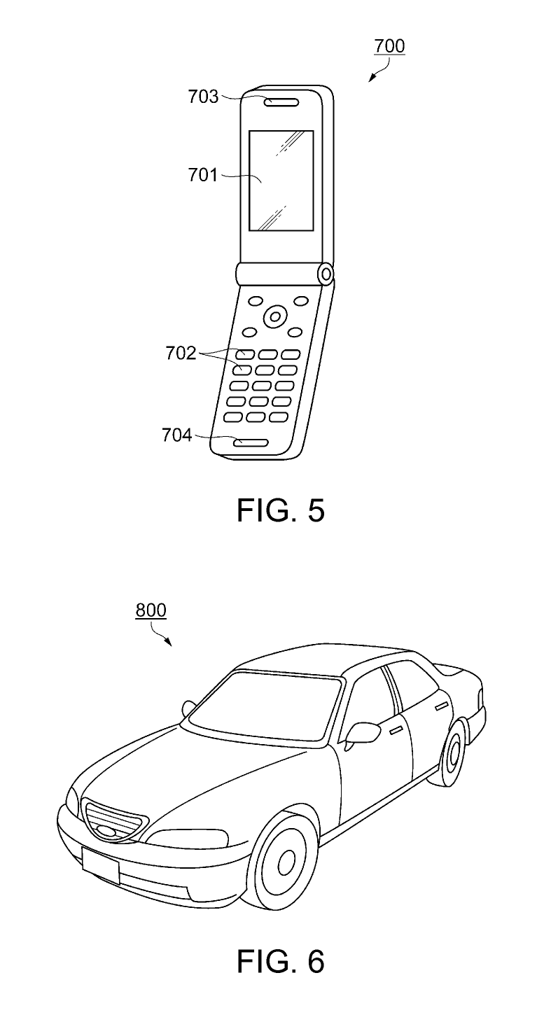

FIG. 5 is a schematic perspective view illustrating the cellular phone as the electronic apparatus.

A cellular phone 700 includes the quartz crystal oscillator as the electronic device described in the above embodiment.

The cellular phone 700 illustrated in FIG. 5 uses the quartz crystal oscillator 1 described above, for example, as a timing device as a reference clock oscillation source and the like, and is configured to include a quartz crystal display device 701, a plurality of operation buttons 702, an earpiece 703, and a mouthpiece 704. Moreover, a shape of the cellular phone is not limited to the type which is illustrated and may be a so-called smart phone type.

Thus, since the cellular phone 700 includes the quartz crystal oscillator described above, it is possible to achieve the effects described above in the above embodiments, to improve the reliability, and to exert excellent performance.

The electronic device such as the quartz crystal oscillator described above is not limited to the cellular phone and it is possible to appropriately be used as a timing device of an electronic apparatus including an electronic book, a personal computer, a television, a digital still camera, a video camera, a video recorder, a navigation apparatus, a pager, an electronic diary, an electronic calculator, a word processor, a workstation, a television telephone, a POS terminal, a game apparatus, a medical apparatus (for example, an electronic thermometer, a blood pressure monitor, a blood glucose meter, an electrocardiogram measuring apparatus, an ultrasonic diagnostic apparatus and an electronic endoscope), a fish finder, various measuring apparatuses, measurement equipment, a flight simulator and the like. In any case, it is possible to provide the electronic apparatus in which the effects described in the above embodiment are achieved, the reliability is improved, and excellent performance is exerted.

### Moving Object

Next, as a moving object including the electronic device described above, a vehicle is described as an example.

FIG. 6 is a schematic perspective view illustrating the vehicle as the moving object.

A vehicle 800 includes the quartz crystal oscillator as the electronic device described in the above embodiment.

For example, the vehicle 800 uses the quartz crystal oscillator 1 described above as a timing device such as a reference clock oscillation source of various electronic control-type apparatuses (for example, an electronic control-type fuel ejection apparatus, an electronic control-type ABS apparatus, an electronic control-type constant speed traveling apparatus, and the like) mounted on the vehicle.

Thus, since the vehicle 800 includes the quartz crystal oscillator described above, it is possible to achieve the effects described in the above embodiment, to improve the reliability, and to exert excellent performance.

The electronic device such as the quartz crystal oscillator described above is not limited to the vehicle 800, and can be appropriately used as a timing device such as a reference clock oscillation source of a moving object including a self-propelled robot, self-propelled transport equipment, a train, a ship, an airplane, a satellite, and the like. In any case, it is possible to provide the moving object in which the effects described in the above embodiment are achieved, the reliability is improved, and excellent performance is exerted.

In addition, the shape of the vibration piece of the quartz crystal oscillator is not limited to the type of the tuning fork type, and may be a double-ended tuning fork type, an AT-cut type, a WT type, an H type, a SAW resonator type, and the like.

Furthermore, the material of the vibration piece is not limited to the quartz crystal and may be a piezoelectric element of lithium tantalate (LiTaO₃), lithium tetraborate (Li₂B₄O₇), lithium niobate (LiNbO₃), lead Zirconate titanate (PZT), zinc oxide (ZnO), aluminum nitride (AlN), or a semiconductor of silicon (Si).

Furthermore, the electronic component is not limited to the vibration piece and, for example, may be a transistor, a temperature sensitive element such as a thermistor, a capacitive element such as a chip capacitor, and a passive element such as a chip inductor (chip coil).

What is claimed is:

1. A package comprising:
a base substrate;
a lid body that is disposed to overlap the base substrate in a plan view when viewed in a thickness direction of the base substrate and has light permeability; and
low melting point glass that is disposed between the base substrate and the lid body, and bonds the base substrate and the lid body,
wherein the low melting point glass has a region of which a width in a cross section along the thickness direction is widened toward a bonding surface of the lid body.

2. The package according to claim 1,
wherein the lid body is glass.

3. The package according to claim 1,
wherein a thickness of the low melting point glass is in a range of 10 μm or more and 100 μm or less.

4. The package according to claim 1,
wherein the low melting point glass contains metal.

5. The package according to claim 1,
wherein the low melting point glass is housed on an inside of the lid body in a plan view when viewed in the thickness direction.

6. A manufacturing method of a package comprising:
preparing a base substrate on which low melting point glass is disposed and a lid body having light permeability; and
bonding the base substrate and the lid body by applying an energy beam from the lid body side to the low melting point glass in a state where the base substrate and the lid body are overlapped through the low melting point glass.

7. The manufacturing method of a package according to 6,
wherein the bonding includes controlling a distance between the base substrate and the lid body.

8. The manufacturing method of a package according to 6,
wherein in the bonding, intensity distribution of the energy beam is flattened in a center portion of the energy beam.

9. The manufacturing method of a package according to 6,
wherein in the bonding, an irradiation area of the energy beam is greater than a plane area of the low melting point glass.

10. An electronic device comprising:
the package according to claim 1; and
an electronic component that is housed in the package.

11. An electronic device comprising:
the package according to claim 2; and
an electronic component that is housed in the package.

12. An electronic device comprising:
the package according to claim 3; and
an electronic component that is housed in the package.

13. An electronic device comprising:
the package according to claim 4; and
an electronic component that is housed in the package.

14. An electronic device comprising:
the package according to claim 5; and
an electronic component that is housed in the package.

15. An electronic apparatus comprising:
the electronic device according to claim 10.

16. An electronic apparatus comprising:
the electronic device according to claim 11.

17. An electronic apparatus comprising:
the electronic device according to claim 12.

18. A moving object comprising:
the electronic device according to claim 10.

19. A moving object comprising:
the electronic device according to claim 11.

20. A moving object comprising:
the electronic device according to claim 12.
